(19) United States
(12) Patent Application Publication
(10) Pub. No.: US 2018/0130719 A1
(43) Pub. Date: May 10, 2018

(54) SEMICONDUCTOR DEVICE PACKAGES AND METHOD OF MANUFACTURING THE SAME

(71) Applicant: Advanced Semiconductor Engineering, Inc., KAOHSIUNG (TW)

(72) Inventors: Yu-An FANG, Kaohsiung (TW); Ying-Chung CHEN, Kaohsiung (TW)

(73) Assignee: Advanced Semiconductor Engineering, Inc.

(21) Appl. No.: 15/347,683

(22) Filed: Nov. 9, 2016

(51) Int. Cl. H01L 23/10; H01L 23/055; H01L 21/52; H01L 23/00

(52) U.S. Cl. CPC H01L 23/10; H01L 23/055; H01L 2224/48227; H01L 24/48; H01L 21/52

(57) ABSTRACT

A semiconductor device package includes a carrier, a lid, an electronic component and a sealant. The carrier has a first surface and a second surface opposite the first surface, and defines a hole extending from the first surface to the second surface. The lid is attached to the first surface of the carrier. The lid and the carrier define a chamber. The electronic component is attached to the first surface of the carrier and is disposed in the chamber. The sealant is attached to the second surface of the carrier and covers the hole.

### BACKGROUND

### 1. Technical Field

The present disclosure relates to a semiconductor device package. In particular, the present disclosure relates to a semiconductor device package including a lid and a method of manufacturing the same.

### 2. Description of the Related Art

In a semiconductor device package, a lid is used to protect a die and other electronic devices on a substrate from moisture, dust, particles or the like. The lid is attached to the substrate by glue to form the semiconductor device package. However, the lid may be detached from the substrate due to a pop-corn effect resulting from thermal cycling (e.g., the semiconductor device package may be heated to cure the glue between the lid and the substrate).

### SUMMARY

In an aspect according to some embodiments, a semiconductor device package includes a carrier, a lid, an electronic component and a sealant. The carrier has a first surface and a second surface opposite the first surface, and defines a hole extending from the first surface to the second surface. The lid is attached to the first surface of the carrier. The lid and the carrier define a chamber. The electronic component is attached to the first surface of the carrier and is disposed in the chamber. The sealant is attached to the second surface of the carrier and covers the hole.

In an aspect according to some embodiments, a method for manufacturing a semiconductor device package includes: (a) providing a carrier defining a through-hole; (b) attaching an electronic component to the carrier; (c) attaching a lid to the carrier to cover the electronic component and define a chamber with the carrier; and (d) applying a sealant material on the carrier to cover the through-hole.

In an aspect according to some embodiments, a method for manufacturing an electronic apparatus includes: (a) providing a first carrier defining a through-hole; (b) attaching an electronic component to the first carrier; (c) attaching a lid to the first carrier to cover the electronic component and define a chamber with the carrier; (d) applying a sealant material on the first carrier to cover the through-hole; and (e) creating a smaller air pressure in the chamber than an ambient air pressure.

### BRIEF DESCRIPTION OF THE DRAWINGS

FIG. 1 is a cross-sectional view of a semiconductor device package in accordance with some embodiments of the present disclosure.

FIG. 2 is a cross-sectional view of another semiconductor device package in accordance with some embodiments of the present disclosure.

FIG. 3A, FIG. 3B, FIG. 3C, FIG. 3D, FIG. 3E and FIG. 3F illustrate a method of manufacturing a semiconductor device package in accordance with some embodiments of the present disclosure.

Common reference numerals are used throughout the drawings and the detailed description to indicate the same or similar elements. Embodiments of the present disclosure will be more apparent from the following detailed description taken in conjunction with the accompanying drawings.

### DETAILED DESCRIPTION

Described in this disclosure are techniques for improved attachment of a lid of a semiconductor device package. Moreover, the techniques may avoid the lid from being detached from a substrate due to a pop-corn effect resulting from thermal cycling.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

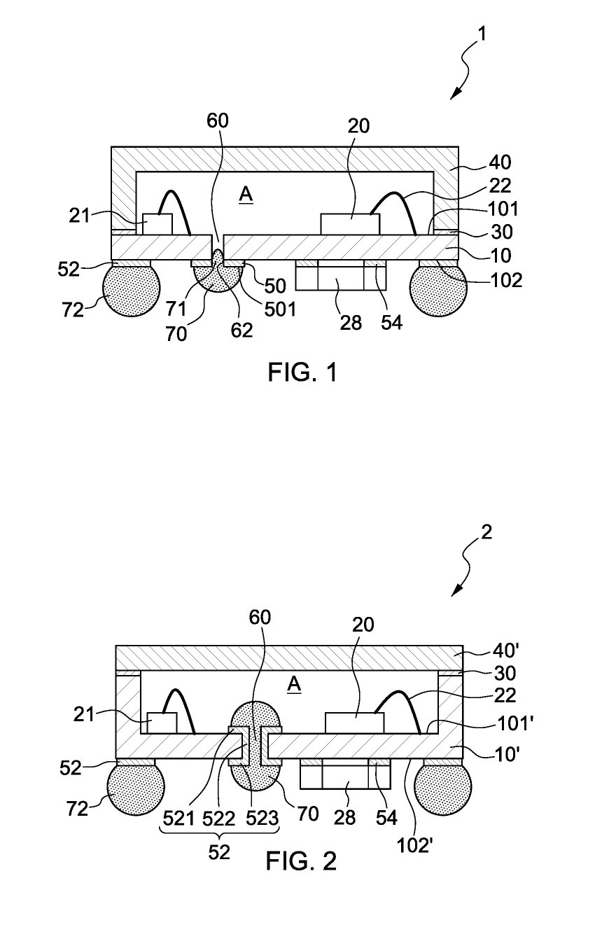

FIG. 1 is a cross-sectional view of a semiconductor device package 1 in accordance with some embodiments of the present disclosure. The semiconductor device package 1 includes a carrier 10, a lid 40, bonding wires 22, electronic components 20 and 21, a pad 50, a sealant 70, solder ball pads 52, a Surface Mount Technology (SMT) pad 54 and an adhesive layer 30. The semiconductor device package 1 shown in FIG. 1 is one example unit formed on a panel prior to singulation, and the panel includes a plurality of such units.

The carrier 10 has an upper surface 101 and a lower surface 102 opposite to the upper surface 101. In some embodiments, the carrier 10 may include silicon, a ceramic material, an organic material (e.g., bismaleimide-triazine (BT) or a glass-reinforced epoxy material (e.g., FR-4)) or another suitable material. A through-hole 60 is formed from the upper surface 101 of the carrier 10 and extends to the lower surface 102. In some embodiments, a metal layer may be disposed on a sidewall of the through-hole 60. In some embodiments, the sidewall of the through-hole 60 may omit a metal layer disposed thereon. Although it is not illustrated in FIG. 1, it is contemplated that the carrier 10 may include a circuitry, such as a redistribution structure which includes conductive traces, pads, vias, or the like.

The lid 40 is attached to the upper surface 101 of the carrier 10 through the adhesive layer 30 or through soldering. The lid 40 and the carrier 10 together define a chamber A, the lid 40 and the carrier 10 can be sealed by the adhesive layer 30 or by soldering, and the sealing may be a hermetic seal. The hermetic seal may be formed by metal bonding, glass frit, anodic bonding, eutectic bonding or fusion bonding. The adhesive layer 30 is cured from, for example, a gel, a glue, or other adhesive material by a heating operation during a manufacturing process of the semiconductor device package 1.

The electronic components 20 and 21 (e.g., semiconductor dies, passive components, or the like) are disposed on the upper surface 101. The electronic components 20 and 21 are disposed in the chamber A. The bonding wires 22 electrically connect the electronic components 20 and 21 to the circuitry of the carrier 10. In some embodiments, the bonding wires 22 may include gold (Au), copper (Cu), or another suitable conductive material.

The pad 50 is disposed on the lower surface 102 of the carrier 10. The solder ball pads 52 are formed on the lower surface 102, and the pad 54 is formed on the lower surface 102. The pad 50 surrounds the through-hole 60. The pad 50 has or defines a through-hole 62 in communication with the through-hole 60. The pad 50 has or defines the through-hole 62 which is aligned with the through-hole 60. The pad 50 has a ring or an annular shape. In some embodiments, the annular pad 50 may include Cu-palladium (Pd)—Au, Cu, nickel (Ni), Pd, Au, or a combination thereof, or other suitable materials.

The sealant 70 may include but is not limited to, for example, solder which may include tin (Sn), tin-silver (SnAg), tin-silver-copper (SnAgCu), or other suitable materials. The sealant 70 is disposed on the pad 50. Bonding components 72 may include but is not limited to, for example, solder, which may including Sn or SnAg, SnAgCu or other suitable materials. In some embodiments, the bonding components 72 (e.g., solder balls) may be disposed on the solder ball pads 52. In some embodiments, the sealant 70 and the bonding components 72 may include a same material.

The pad 50 is disposed between the sealant 70 and the lower surface 102 of the carrier 10. A lateral dimension (e.g., a width) of the sealant 70 adjacent to the pad 50 is greater than a lateral dimension (e.g., a width) of the through-hole 62, and is greater than a lateral dimension (e.g., a width) of the through-hole 60. In some embodiments, the sealant 70 covers substantially an entirety of an opening of the through-hole 62, and covers substantially an entirety of an opening of the through-hole 60. The sealant 70 seals the through-holes 60 and 62. The sealant 70 hermetically seals the through-holes 60 and 62. The sealant 70 may protect the electronic components 20 and 21, which reside in the chamber A, from damage or contamination (e.g., particles, moisture, and the like).

The sealant 70 includes a protrusion 71 extending into the through-hole 60. The protrusion 71 has a curved or arcuate end. The protrusion 71 hermetically seals the through-hole 60. A pressure in the chamber A may be relatively lower than an ambient air pressure, and the pressure in the chamber A may avoid the pop-corn effect during various thermal cycles in the manufacturing process.

In some embodiments, an electronic component 28 (e.g., a passive component) is disposed on the lower surface 102 of the carrier 10 and is electrically connected to the pad 54. A thickness of the passive component 28 and a thickness of the sealant 70 may be less than a thickness of the bonding components 72 so that the passive component 28 and the sealant 70 will be accommodated in a space defined by the bonding components 72, the carrier 10 and a mother board (not shown) when the semiconductor device package 1 has been bonded to the mother board by the bonding components 72. In some embodiments, the electronic components 20 and 21 in the semiconductor device package 1 can be isolated from air/external environment. During a delivery process, the structure of the semiconductor device package 1 can be used to protect the electronic components 20 and 21 from moisture, dust, particles or the like, which may cause a sensitivity of the semiconductor device package 1 to be lower.

FIG. 2 is a cross-sectional view of a semiconductor device package 2 in accordance with some embodiments of the present disclosure. The structure of the semiconductor device package 2 is similar in some respects to the structure of the semiconductor device package 1, except that a carrier 10′ includes a recessed portion. The semiconductor device package 2 shown in FIG. 2 is one example unit formed on a panel prior to singulation, and the panel includes a plurality of such units.

The carrier 10′ may include a ceramic substrate. A lid 40′ covers the recessed portion of the carrier 10′. The lid 40′ may include silicon, glass, or other suitable material. The lid 40′ and the carrier 10′ can be sealed by an adhesive layer 30 or by soldering, and the sealing may be a hermetic seal. The hermetic seal may be formed by metal bonding, glass frit, anodic bonding, eutectic bonding or fusion bonding.

A through-hole 60 is formed from an upper surface 101′ of the carrier 10′ and extends to a lower surface 102′. A metal layer 52 includes three portions, wherein a first portion 521 is disposed on the upper surface 101′ of the carrier 10′, a second portion 522 is disposed on a sidewall of the carrier 10′, and a third portion 523 is disposed on the lower surface 102′ of the carrier 10′. A sealant 70 covers the first portion 521, the second portion 522 and the third portion 523.

A passive component 28 and the sealant 70 may be accommodated in a space defined by bonding components 72, the carrier 10′ and a mother board (not shown) when the semiconductor device package 2 has been bonded to the mother board by the bonding components 72. In some embodiments, electronic components 20 and 21 in the semiconductor device package 2 can be isolated from air/external environment. During a delivery process, the structure of the semiconductor device package 2 can be used to protect the electronic components 20 and 21 from moisture, dust, particle or the like, which may cause a sensitivity of the semiconductor device package 2 to be lower.

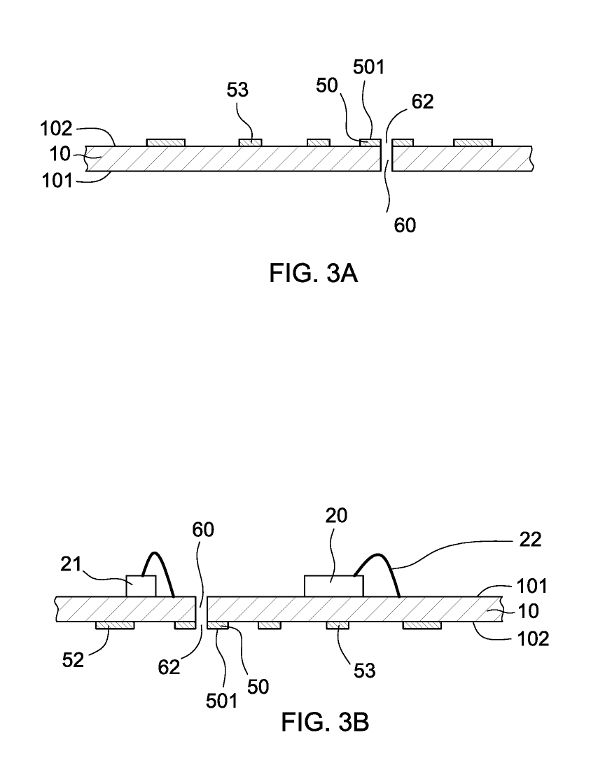

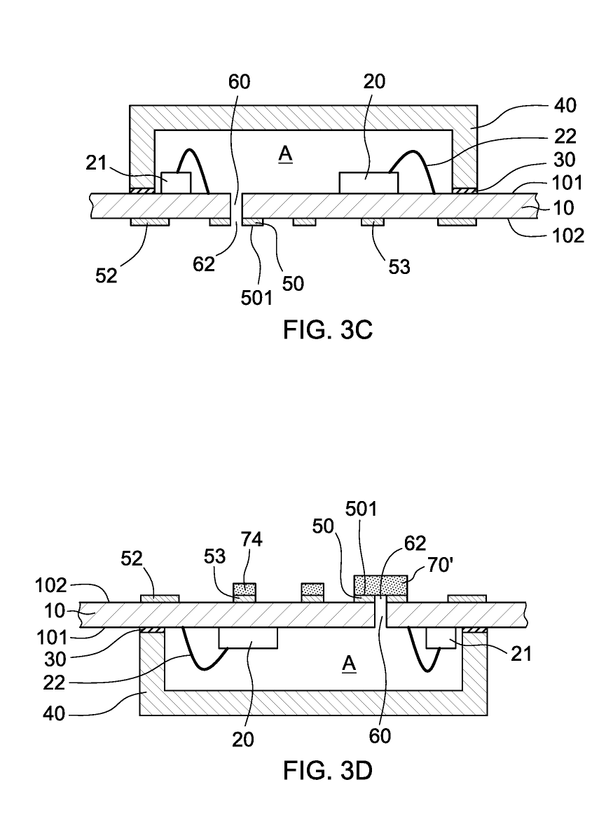

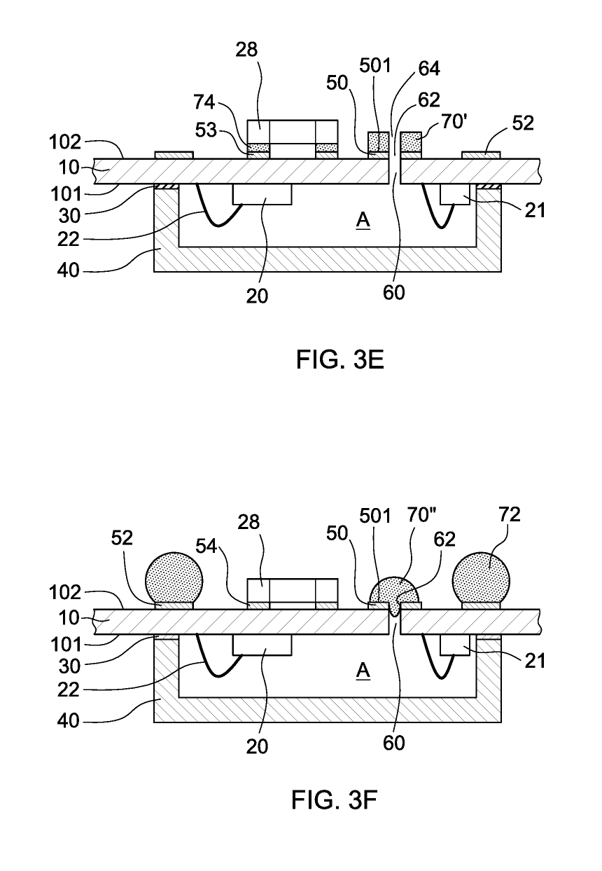

FIGS. 3A-3F illustrate a method of manufacturing a semiconductor device package 1 in accordance with some embodiments of the present disclosure. Referring to FIG. 3A, a carrier 10 is provided. The carrier 10 has a surface 101 and a surface 102 opposite the surface 101. In some embodiments, the carrier 10 may include silicon, a ceramic material, an organic material (e.g., BT or FR-4) or another suitable material. Solder ball pads 52 are formed on the surface 102. A pad 53 is formed on the surface 102.

A through-hole 60 is formed from the surface 102 of the carrier 10 and extends to the surface 101. The through-hole 60 is formed by machine drilling techniques or laser drilling techniques. An annular pad 50 is formed on the surface 102 of the carrier 10 by plating techniques. The annular pad 50 has a surface 501 and surrounds an opening of the through-hole 60. The annular pad 50 has or defines a through-hole 62 formed by machine drilling techniques or laser drilling techniques. The through-hole 62 communicates with the through-hole 60. In some embodiments, the annular pad 50 may include Cu—Pd—Au, Cu, Ni, Pd, Au, or a combination thereof, or another suitable material. In some embodiments, a solder mask layer (not shown) may cover the annular pad 50. In some embodiments, the annular pad 50 may be formed and extends to cover a portion of the surface 101 of the carrier 10, a sidewall of the through-hole 60, and a portion of the surface 102 of the carrier 10.

Referring to FIG. 3B, electronic components 20 and 21 are attached to the surface 101 of the carrier 10. Bonding wires 22 are electrically connected to the electronic components 20 and 21. One end of each bonding wire 22 is attached to the surface 101 of the carrier 10 and another end of the bonding wire 22 is attached to the corresponding electronic component 20 or 21.

Referring to FIG. 3C, a lid 40 is attached to the surface 101 of the carrier 10 through an adhesive layer 30 to cover the electronic components 20 and 21. The lid 40 defines a chamber A with the carrier 10. The adhesive layer 30 is cured from, example, a gel, a glue, or other adhesive material by a heating process during one thermal cycle of the manufacturing process of the semiconductor device package 1. In some embodiments, an adhesive material of the adhesive layer 30 may be replaced by metal bonding, glass frit, anodic bonding, eutectic bonding or fusion bonding.

Referring to FIG. 3D, a sealant material 70′ (e.g., solder) is applied on the surface 501 of the annular pad 50 and covers the through-holes 60 and 62. In some embodiments, the sealant material 70′ may be solder including Sn or other suitable materials. A solder paste 74 can be applied on the pad 53 by screen printing techniques. The sealant material 70′ and the solder paste 74 may be applied in the same stage and can be applied on the annular pad 50 and the pad 53 by screen printing techniques.

Referring to FIG. 3E, a passive component 28 is disposed on the solder paste 74 by Surface Mount Technology (SMT). After the passive component 28 is disposed on the pad 53, a heating operation is performed on the structure as shown in FIG. 3E. A flux is applied to the sealant material 70′ to aid in melting of the sealant material 70′. The sealant material 70′ is softened during the heating operation. An air in the chamber A will expand during the heating operation; thus, a pressure in the chamber A is larger than an external air pressure. The air in the chamber A, which is heated, may expand to break through the sealant material 70′ to create a through-hole 64. The through-holes 60, 62 and 64 may allow part of the expanded air to exit the chamber A. Since the sealant material 70′ is at a molten state and is in a liquid state, the air in the chamber A can be expelled or vented out of the chamber A through the through-holes 60, 62 and 64.

The air released by through-holes 60, 62 and 64 from the chamber A during the heating operation may avoid the pop-corn effect. Bonding between the lid 40 and the carrier 10 may not be damaged because the expanded air during thermal cycling is released by the through-holes 60, 62 and 64 to avoid the pop-corn effect. Bonding between the lid 40 and the carrier 10 may not be damaged due to the structural features of the carrier 10, the pad 50 and the sealant material 70′.

Referring to FIG. 3F, when little or no air in the chamber A exits through the sealant material 70′, a shape of the sealant material 70′ may change to a shape of a sealant 70″, for example, a round or hemispherical shape. The shape of the sealant material 70′ may change to the shape of the sealant 70″, for example, a round or hemispherical shape, when the heating temperature reaches about 260° C. to 280° C. Bonding components 72 are formed on the solder ball pads 52. A total thickness of the passive component 28, the solder paste 74 and the pad 53 may be less than a thickness of the bonding components 72. The solder paste 74 combines with the pad 53 to form a SMT pad 54 due to metal wetting.

The sealant 70″ covers or seals the through-holes 60 and 62. When the temperature drops during a cooling operation, the air pressure in the chamber A is smaller than the external air pressure (e.g., a smaller pressure is created in the chamber A). When the temperature drops, the sealant 70″ becomes solid and a portion of the sealant 70″ may be drawn into the through-holes 60 and 62 to form a protrusion 71 due to the relatively smaller air pressure in the chamber A to form the semiconductor device package 1 as shown in FIG. 1. External air thus cannot enter the chamber A due to coverage by the solid sealant 70″.

After the sealant 70″ is solidified, the semiconductor device package 1 is sealed from air/external environment. The semiconductor device package 1 may be attached to a mother board through reflowing of the bonding components 72. Since a flux is not applied to the sealant 70″ at the reflow stage, and the sealant 70″ has an oxide on its surface, a melting point of the sealant 70″ is larger than a melting point of the bonding components 72. Therefore, the sealant 70″ does not melt during the reflow stage so that the semiconductor device package 1 maintains the seal from air/external environment.

It is contemplated that the semiconductor device package 1 may be attached to another carrier (such as a system board, which is not shown in the drawings), and the semiconductor device package 1 may undergo another heating operation. The air (which has a relatively lower pressure) in the chamber A is heated in the operation of attaching the semiconductor device package 1 to the system board. The expansion of the air (which has a relatively lower pressure) in the chamber A in the operation of attaching the semiconductor device package 1 to the system board is compensated. Pop-corn effect is avoided by the relatively lower pressure in the chamber A.

Also, the semiconductor device package 1 maintains the seal from air/external environment during a singulation operation of a panel. In addition, during a subsequent packing stage and a subsequent delivery process, the semiconductor device package 1 maintains the seal from air/external environment (e.g., a state of hermetic sealing) and is not damaged due to the subsequent delivery process.

A similar method can be used for manufacturing the semiconductor device package 2 as shown in FIG. 2, where a sealant material is applied on both the first portion 521 of the metal layer 52 disposed on the upper surface 101′ of the carrier 10′, and on the third portion 523 of the metal layer 52 disposed on the lower surface 102′ of the carrier 10′.

As used herein, the singular terms “a,” “an,” and “the” may include plural referents unless the context clearly dictates otherwise.

As used herein, the terms “substantially,” “approximately,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

In the description of some embodiments, a component provided “on” or “over” another component can encompass cases where the former component is directly on (e.g., in physical or direct contact with) the latter component, as well as cases where one or more intervening components are located between the former component and the latter component.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor device package, comprising:
a carrier having a first surface and a second surface opposite the first surface, and defining a hole extending from the first surface to the second surface;
a lid attached to the first surface of the carrier, the lid and the carrier defining a chamber;
an electronic component attached to the first surface of the carrier and disposed in the chamber, wherein the electronic component is spaced apart from the lid; and
a sealant attached to the second surface of the carrier and covering the hole.

2. The semiconductor device package of claim 1, wherein the sealant comprises a protrusion within the hole.

3. The semiconductor device package of claim 2, wherein the protrusion comprises a curved or arcuate end.

4. The semiconductor device package of claim 1, wherein the sealant has a width greater than a width of the hole.

5. The semiconductor device package of claim 1, further comprising a pad surrounding the hole on the second surface of the carrier, wherein the pad is disposed between the sealant and the second surface of the carrier.

6. The semiconductor device package of claim 5, wherein the pad defines a hole, and the sealant has a width greater than a width of the hole defined by the pad.

7. A method for manufacturing a semiconductor device package, comprising:
(a) providing a carrier defining a through-hole;
(b) attaching an electronic component to the carrier;
(c) attaching a lid to the carrier to cover the electronic component and define a chamber with the carrier, wherein the electronic component is disposed in the chamber and is spaced apart from the lid; and
(d) applying a sealant material on the carrier to cover the through-hole.

8. The method of claim 7, further comprising (e) performing a heating operation.

9. The method of claim 8, wherein (e) comprises applying a flux to the sealant material.

10. The method of claim 8, wherein the sealant material is softened during the heating operation, and air in the chamber is expelled from the chamber through a hole formed in the softened sealant material.

11. The method of claim 8, wherein a sealant is formed from the sealant material to seal the through-hole.

12. The method of claim 8, further comprising (f) performing a cooling operation.

13. The method of claim 12, wherein the sealant material is drawn into the through-hole in (f) to seal the through-hole.

14. The method of claim 7, further comprising forming a pad surrounding the through-hole on the carrier, prior to (d).

15. The method of claim 14, wherein the sealant material is applied to the pad in (d).

16. A method for manufacturing an electronic apparatus, comprising:
(a) providing a first carrier defining a through-hole
(b) attaching an electronic component to the first carrier;
(c) attaching a lid to the first carrier to cover the electronic component and define a chamber with the first carrier, wherein the electronic component is disposed in the chamber and is spaced apart from the lid;
(d) applying a sealant material on the first carrier to cover the through-hole; and
(e) creating a smaller air pressure in the chamber than an ambient air pressure.

17. The method of claim 16, wherein (e) comprises performing a first heating operation.

18. The method of claim 17, wherein (e) further comprises performing a cooling operation subsequent to the first heating operation.

19. The method of claim 17, wherein performing the first heating operation comprises applying a flux to the sealant material.

20. The method of claim 17, further comprising (f) bonding the first carrier to a second carrier by performing a second heating operation.
